(19) United States
(12) Patent Application Publication
(10) Pub. No.: US 2025/0208521 A1
(43) Pub. Date: Jun. 26, 2025

(54) ARRANGEMENT, METHOD AND COMPUTER PROGRAM PRODUCT FOR CALIBRATING FACET MIRRORS

(71) Applicant: Carl Zeiss SMT GmbH, Oberkochen (DE)

(72) Inventors: Stefan LIPPOLDT, Aalen (DE); Reimar FINKEN, Westhausen (DE); Florian BAUMER, Oberkochen (DE)

(21) Appl. No.: 19/074,849

(22) Filed: Mar. 10, 2025

Related U.S. Application Data
(63) Continuation of application No. PCT/EP2023/076093, filed on Sep. 21, 2023.

(30) Foreign Application Priority Data
Sep. 26, 2022 (DE) 10 2022 210 158.8

(51) Int. Cl. G03F 7/00

(52) U.S. Cl. CPC G03F 7/706845; G03F 7/70075

(57) ABSTRACT

The techniques disclosed herein relate to an arrangement, a method and a computer program product for system-integrated calibration of the facet mirrors of a microlithographic illumination system. Calibration beam paths leading via the facet mirrors between a calibration radiation source and a calibration radiation sensor are defined, only one pivotable micromirror of the single facet mirror constructed from micromirrors being involved in each of said calibration beam paths. By pivoting the micromirror involved in a defined calibration beam path, a specific optimum pivot position, whose underlying orientation of the micromirror can also be calculated geometrically, can be found on the basis of the calibration radiation sensor. By comparing the calculated orientation with the orientation determined by an orientation sensor at the micromirror, the orientation sensor of the micromirror of the facet mirror can be calibrated.

### CROSS-REFERENCE TO RELATED APPLICATION

This is a Continuation of International Application PCT/EP2023/076093, which has an international filing date of Sep. 21, 2023, and the disclosure of which is incorporated in its entirety into the present Continuation by reference. This Continuation also claims foreign priority under 35 U.S.C. § 119(a)-(d) to and also incorporates by reference, in its entirety, German Patent Applications DE 10 2022 210 158.8 filed on Sep. 26, 2022.

### FIELD

The techniques disclosed herein relate to an arrangement, a method and a computer program product for system-integrated calibration of the facet mirrors of a microlithographic illumination system.

### BACKGROUND

Microlithography is used for producing microstructured component parts, such as for example integrated circuits. The projection exposure apparatus used in the process comprises an illumination system and a projection system. The image of a mask (also referred to as a reticle) illuminated by the illumination system is projected, in a manner to reduce the size thereof, via the projection system onto a substrate, for example a silicon wafer, which is coated with a light-sensitive layer and arranged in the image plane of the projection system, in order to transfer the mask structure to the light-sensitive coating of the substrate.

Generally, two facet mirrors are arranged in the beam path between the actual exposure radiation source and the mask to be illuminated in the case of illumination systems, in particular of projection exposure apparatuses designed for the EUV range, that is to say for exposure wavelengths from 5 nm to 30 nm, and said mirrors allow homogenization of the radiation in a manner essentially comparable to the principle of a fly's eye condenser. The closer facet mirror in the beam path of the exposure radiation source is often a so-called field facet mirror, and the other facet mirror is a so-called pupil facet mirror.

In order to be able to produce different intensity and/or angle of incidence distributions during the illumination of the mask, it is known for the facets of one of the two facet mirrors—in particular those of the field facet mirror—to be formed from electromechanically pivotable micromirrors. Even though it may be known in the prior art to form both facet mirrors from corresponding micromirrors, it is sufficient for a large number of intended uses if the respectively other facet mirror—i.e., in particular the pupil facet mirror—has stationary facets or facets that are adjustable, in particular tiltable, merely between two defined positions—namely a reflective position and a non-reflective position. If only one of the two facet mirrors is constructed from micromirrors, the complexity of the illumination system and in particular the control thereof is accordingly reduced.

In order to attain the required precision when setting a desired intensity and angle of incidence distribution, it is necessary, in principle, to be able to accurately set the orientation of the individual micromirrors of the facet mirror constructed therefrom. In this case, the micromirrors also comprise an orientation sensor, with which the orientation of the micromirror can be read and verified generally in two spatial directions, in addition to the microelectromechanical drive required for pivoting the mirror.

The relationship between the actual orientation of the micromirror and the value determined by way of the orientation sensor is typically non-linear and requires calibration, the latter resulting in a sensor characteristic curve that renders the values determined by the orientation sensor actually usable in the first place for controlling the micromirrors. An accuracy of the order of 10 rad is beneficial for application in microlithography.

It has been found that the sensor characteristic curves of the orientation sensors are subject to a drift and possibly other similar transformations as well, with the result that the accuracy of the orientations of the micromirrors determined by way of the orientation sensors decreases over time, whereby the precision of the setting of the intensity and angle of incidence distributions may then also decrease.

Thus, continuous operation of an illumination system comprising a facet mirror constructed from electromechanically pivotable micromirrors requires a regular recalibration. However, known calibration methods which require opening of the illumination system and/or the application of an external measurement sensor system are complicated and time-consuming.

Further calibration methods are described in the laid-open applications DE 10 2015 219 447 A1 and DE 10 2019 204 165 A1, and also in the as yet unpublished German patent application 10 2022 203 369.8.

The disclosed techniques are based on the object of providing an arrangement, a method and a computer program product for system-integrated calibration of the facet mirrors of a microlithographic illumination system which allow the recalibration in question to be carried out in system-integrated fashion—i.e., without the use of an external measurement sensor system and preferably also without opening of the illumination system.

### SUMMARY

The disclosed techniques relate to an arrangement for system-integrated calibration of a facet mirror of a microlithographic illumination system, wherein the facet mirror to be calibrated is configured as a microelectromechanical system with a multiplicity of individually pivotable micromirrors with a respective orientation sensor for determining the orientation of the micromirror and is arranged positionally fixed in the beam path of the illumination optical unit of the illumination system in such a way that beams emanating from an exposure radiation source are deflected onto the reticle plane of the illumination system by the exposure optical unit comprising the facet mirror to be calibrated and a further facet mirror without a microelectromechanical system, wherein at least one calibration radiation source device and at least one calibration radiation sensor device are provided, of which one device is arranged near the reticle plane of the illumination system away from the region provided for a reticle and the exposure thereof, and the other device is arranged in such a way that at least one calibration beam path proceeding from one of the calibration radiation source(s) via a predefined micromirror of the facet mirror to be calibrated, given a suitable pivot position of the micromirror, and a predefined facet of the other facet mirror to one of the calibration radiation sensor(s) is definable.

Furthermore, the disclosed techniques relate to a method for calibrating a facet mirror—constructed from micromirrors—of a microlithographic illumination system using an arrangement according to the disclosed techniques, comprising the steps:
a) pivoting a micromirror of the facet mirror constructed therefrom, said micromirror being involved in a defined calibration beam path leading from a calibration radiation source device via an illumination optical unit comprising at least two facet mirrors to a calibration radiation sensor device, at least over the pivot range in which the calibration beam path is incident on the calibration radiation sensor device and is detected by the latter;
b) determining the optimum pivot position of the pivoted micromirror with the aid of the calibration radiation sensor device, in the case of which the calibration beam path is incident as optimally as possible on the radiation detector;
c) ascertaining the orientation of the micromirror determined by the orientation sensor of the pivoted micromirror for the optimum pivot position determined;
d) comparing the orientation determined by the orientation sensor of the pivoted micromirror with an orientation calculated from the defined calibration beam path; and
e) recalibrating the orientation sensor of the micromirror on the basis of the comparison carried out.

Finally, the disclosed techniques also relate to a computer program product or a set of computer program products, comprising program parts which, when loaded into a computer or into networked computers connected to an arrangement according to the disclosed techniques, are designed to carry out the method according to the disclosed techniques.

Firstly, some terms used in the context of the disclosed techniques are explained:

The term “micromirrors” denotes small, often rectangular, mirrors with an edge length of up to 1 mm×1 mm, 1.5 mm×1.5 mm or 2 mm×2 mm. If a micromirror itself is not rectangular, then the minimum rectangle surrounding it has the sizes mentioned.

A “microelectromechanical system” (MEMS) for facet mirrors, in addition to comprising the orientation sensor, also comprises actuators that enable the micromirrors of a facet mirror to be individually pivoted. The microelectromechanical system can be realized using microsystems technology, in particular.

The term “pivoting” relates to the possibility of setting the orientation of a micromirror practically as desired within a pivot range. In this case, the pivoting can be possible about two non-parallel axes, in particular, thus resulting in e.g., a conical or pyramidal pivot range. The pivoting is preferably effected systematically, that is to say that a micromirror is controlled in a targeted manner so that it is pivoted in accordance with a predefined movement pattern for the pivot movement.

An “orientation sensor” makes it possible, in principle, for an orientation of the micromirror to be determined unambiguously. If the micromirror can be pivoted in two directions, the orientation sensor regularly also yields two values, each reflecting the pivot position in one direction. By way of example, the orientation sensor can be of capacitive design, in which case e.g., the capacitance of two intermeshing combs is measured, one of which is stationary and the other is concomitantly moved with the micromirror. The measured capacitance then reflects the pivot position of the micromirror.

The “calibration of a facet mirror” denotes a process which is intended to ensure that, in the case of an angular position predefined by a suitable signal for a specific micromirror, this angular position is also actually adopted by the respective micromirror. Particularly if the actual angular position of a micromirror is verifiable here by an orientation sensor, in principle, the calibration of a facet mirror encompasses the calibration of the orientation sensor, in particular. In this case, “calibration” generally denotes the adaptation of a predefined transfer function of a first measured value to a measured variable which reflects a second measurable value. Thus, in the case of an orientation sensor of a micromirror, one analogue electrical or digitized signal or a plurality of analogue electrical or digitized signals is or are converted into one angle specification or a plurality of angle specifications, for example, with the aid of a transfer function adapted by calibration, said angle specifications reflecting the orientation of the micromirror vis-à-vis a defined zero orientation. Depending on the transfer function and, in particular, depending on the number of changeable parameters thereof, it is advantageous to carry out a plurality of measurements of the first value for different second values for the purpose of complete calibration in order to enable a sufficient number of support points for a complete adaptation of the transfer function or all of its parameters. Here, it is the fundamental target of a calibration to adapt the transfer function sufficiently exactly so that the measured variable ascertained from the first measured value corresponds as accurately as possible to the actual second value without the second value itself needing to be measured. As a rule, there even is a specification for the accuracy to be attained with the aid of the calibration, which accuracy should be attained over the entire value range or a specified portion of the value range of the first measured value.

Before the actual calibration is carried out in order to attain the specified accuracy, a certain “basic calibration” (which optionally still needs to be verified or can be verified) is assumed or else a basic calibration is carried out. There is also an adaptable transfer function, as is also adapted during the actual calibration, in a “basic calibration”; the transfer functions of the basic calibration and the actual calibration are often even identical. However, a transfer function with a basic calibration has an accuracy orders of magnitude generally lower than the subsequent completely calibrated transfer function. Nevertheless, it is helpful as a starting point for the actual calibration since the basic calibration is at least in the vicinity of the ultimately desired calibration, hence allowing the effort for the actual calibration to be lower.

If one or more facets of a facet mirror are configured to be merely “tiltable”, the facet and in particular its reflective surface can move between two defined end positions—namely in general a position in which the facet can in principle participate in a beam path from exposure source and reticle plane, and a position in which this is not the case. Optionally, discrete intermediate positions can also be defined as well. Even if it is possible to realize a corresponding situation similar to a pivot movement, such a tilt movement nevertheless does not include pivoting within the meaning of the present disclosed techniques since, in principle, it is not possible to effect targeted adopting of any desired intermediate position between the aforementioned defined end positions and/or discrete intermediate positions. Consequently, tiltable facets generally also do not have an orientation sensor of the kind provided for micromirrors.

A device is situated “near a plane” if the distance between the device and the plane is up to 500 mm, preferably up to 200 mm, more preferably up to 100 mm. It goes without saying that here the term also encompasses the arrangement of the device directly in the plane, i.e., at a distance of 0 mm therefrom. If the device has a larger extent in the direction of the distance, the distance between a device and a plane can also be determined using a relevant, in particular active, surface of the device. The active surface can be e.g., the sensor surface in the case of a sensor device, and e.g., the radiation exit surface in the case of a radiation source device.

A device is deemed to be configured as “planar” if its relevant, in particular active, surface has a two-dimensional extent which is larger than in the case of customary non-planar configuration variants. A radiation source device or its exit surface is deemed to be planar, for example, if the radiation source can no longer be regarded as punctiform in the sense of point light when viewed by a person skilled in the art. A sensor or its sensor surface is deemed to be planar if, when the sensor is triggered, the location of incidence on the sensor surface cannot meaningfully be equated at least approximately with the position of the sensor surface itself. In connection with the present disclosed techniques, a planar configuration is present e.g., in particular if the device in question or its relevant, in particular active, surface or the rectangle enclosed by the surface is larger than 2 mm×5 mm, 4 mm×50 mm or 10 mm×100 mm.

The disclosed techniques have recognized that it is possible to calibrate, in particular recalibrate, a facet mirror—constructed from pivotable micromirrors—of the illumination system in system-integrated fashion, that is to say for example it is possible to improve the accuracy of a sensor characteristic curve of individual micromirrors of the facet mirror which is available in principle but possibly no longer accurate on account of drift, by way of only minimal change, if required at all, to known illumination systems—in the extreme case, merely by the provision of a single calibration radiation sensor (or a device including such a sensor, referred to hereinafter interchangeably) in the reticle plane. In particular, no additional moving parts need be provided for this purpose.

The disclosed techniques exploit the highly accurate positionally fixed arrangement of the generally two facet mirrors required for illumination in the field of microlithography, the geometry and optical properties of which facet mirrors are moreover likewise known, in order to generate a calibration beam path proceeding from a calibration radiation source (or a device including such a source, referred to hereinafter interchangeably) to a calibration radiation sensor device by way of suitable pivoting of one of the micromirrors of the facet mirror therefrom together with the other facet mirror, only pivoted micromirrors—mentioned for this purpose—of the facet mirror constructed from micromirrors being involved in said calibration beam path. In order to ensure this, the remaining micromirrors of the facet mirror in question should generally be oriented such that the beam paths passing via them, if appropriate, are definitely not incident on the calibration radiation sensor. It goes without saying that it is also possible for any desired further optical components, such as additional stationary deflection mirrors, etc., to be involved in the calibration beam path.

In this case, the other facet mirror is a facet mirror without microelectromechanically pivotable micromirrors. By way of example, the other facet mirror can thus have exclusively stationary and/or merely tiltable facets.

Since the device(s) provided near the reticle plane is/are arranged away from the region in which the reticle is arranged or at least in which the reticle is illuminated, and moreover no structural change to the facet mirrors is required, the basic functionality of the illumination system is not restricted. Via a suitable pivoting of the micromirrors of the facet mirror constructed therefrom, it is furthermore possible to achieve the known exposure scenarios for a reticle arranged in the reticle plane. It is assumed here, of course, that the device(s) not provided near the reticle plane in the arrangement according to the disclosed techniques also does/do not restrict the basic functionality of the illumination system, e.g., by virtue of shadow casting or the like. It is even possible to calibrate a micromirror in parallel with the illumination of the reticle, i.e., in particular to cause the beam path passing via this micromirror to be incident as a calibration beam path on the calibration radiation sensor, in principle. In this case, the region provided for the reticle in the reticle plane also encompasses in particular such regions in which the reticle is not arranged permanently, but rather is also situated only at times, e.g., on account of the reticle being displaced in a so-called scanning direction.

For a beam path as provided according to the disclosed techniques, it is possible on the one hand to mathematically determine the optimum orientation of the micromirror to be calibrated. For this purpose, in addition to knowledge of the arrangement and properties of the components of the illumination system, in particular the facet mirrors, in general it is necessary to know just the position and possibly the orientation of the calibration radiation source device and/or calibration radiation sensor device involved in the beam path in relation to the illumination system or the components thereof. Depending on the configuration and arrangement of the calibration radiation source device and/or calibration radiation sensor device in question, the position of at least one of the devices must be known exactly, while the position of the other device may not need to be known, or at least not known exactly.

On the other hand, by pivoting the micromirror involved in the beam path and observing the signal of the calibration radiation sensor device, the pivot range of the micromirror can be “scanned” until, for example, the greatest possible intensity is established at the calibration radiation sensor device or the beam path is incident at a predefined point on the calibration radiation sensor device, at which generally the desired optimum pivot position of the micromirror has been attained. By comparing the orientation of the micromirror determined by the orientation sensor in conjunction with the optimum pivot position found with the mathematically determined optimum orientation, it is possible to calibrate the orientation sensor at least for this specific orientation.

If this process is repeated for a specific micromirror with a sufficient number of different beam paths each requiring a different orientation of the micromirror, this yields a corresponding number of support points which can enable a sufficiently accurate calibration of the orientation sensor over the entire pivot range. Depending on which facet mirror is constructed from micromirrors, however, more than one calibration radiation source device and/or more than one calibration radiation sensor device may be required here in order to be able to attain corresponding different beam paths. Alternatively or additionally, the device—arranged in particular near the reticle plane—can also be configured in planar fashion. A corresponding configuration increases the number of calibration beam paths possible, in principle, from which a specific calibration beam can then be selected.

The at least one of the calibration radiation sensor device(s) can be an intensity detector, that is to say a detector which can be used to measure the intensity of the radiation incident over the entire detector surface in a wavelength range acquirable by the detector. A stop can be provided for clearly delimiting the detector surface relevant to the intensity measurement.

It is also possible for the at least one of the calibration radiation sensor device(s) to comprise a one- or two-dimensional array sensor, e.g., a CCD array sensor or an active pixel sensor. With a one-dimensional array sensor, it is possible to determine the position of the incidence of radiation on the array sensor in the direction of the one dimension, wherein the array sensor, in the case of a desired planar configuration, can be extended in the direction perpendicular thereto. With a two-dimensional array sensor, which is planar per se, the two-dimensionality of the active sensor surface may regularly also allow the position of the centre point of the maximum intensity on the sensor surface, and hence the point of incidence of a beam path, to be determined in addition to the intensity of the radiation incident on said sensor, which can further increase the accuracy of the calibration if the arrangement of the sensor is accurately known. If the calibration radiation sensor device or the sensor thereof is of appropriate size, it is also possible for a plurality of beam paths to be incident at a sufficient distance simultaneously on the calibration radiation sensor device, whereby a parallel calibration of a plurality of micromirrors becomes possible. This already holds true, in principle, for a configuration with a one-dimensional array sensor, but in particular for a configuration with a two-dimensional array sensor.

In principle, it is also possible to determine the optimum pivot position of a micromirror for a defined beam path on the basis of the pivot range over which radiation is even incident on a calibration radiation sensor device, if a constant (mis-)calibration over the entire pivot range is assumed. If the contour of the pivot range in question is thus determined, the optimum pivot position can be determined geometrically. In this case, it may even be sufficient for the at least one of the calibration radiation sensor device(s) to be a binary detector which merely specifies whether or not radiation emanating from one of the calibration radiation source device(s) is incident on said detector.

The at least one of the calibration radiation sensor device(s) can also be provided with a narrowband wavelength filter adapted to the wavelength of at least one portion of the calibration radiation source device(s). This can reduce a possible falsification of the measurement result of the respective calibration radiation sensor by stray radiation that does not originate from any of these calibration radiation source devices, for example stray radiation emanating from the exposure radiation source of the illumination system.

In principle, the exposure radiation source of the illumination system itself can be used as the calibration radiation source device or as one of a plurality of calibration radiation source devices. Said exposure radiation source can also be an EUV exposure radiation source, in particular. The calibration radiation sensor device(s) provided for detecting a beam path emanating from such a calibration radiation source device must then be designed for detecting radiation in the corresponding wavelength range.

It is also possible for one or a plurality of calibration radiation source device(s) each to be a separate radiation source, which are preferably arranged in the region of the intermediate focus of the exposure radiation source—i.e., in particular near or in the intermediate focal plane. A corresponding separate radiation source preferably emits light in the visible range. For this purpose, the radiation source can comprise, for example, a high-power light-emitting diode, for example with a light output in the wavelength range from 400 nm to 500 nm, at a radiant flux from 500 mW to 1.5 W in the case of a luminous area ranging from 0.5 mm×0.5 mm to 2 mm×2 mm, or comprise a laser as actual light source, which however is preferably arranged in fibre-coupled fashion and at a distance from the actual location of the radiation source, so that the radiation source or the light exit opening of the coupled fibre can be arranged in space-saving fashion in the interior of the illumination system and as little heat as possible is introduced into the illumination system.

The number, arrangement and/or configuration of the at least one calibration radiation source device and/or of the at least one calibration radiation sensor device, as described by way of example above, are/is preferably chosen in such a way that at least one, preferably at least three, preferably at least five, calibration beam paths is/are definable for at least one portion, preferably for each micromirror, of the facet mirror constructed therefrom. If a corresponding calibration beam path is defined for each micromirror, a minimum calibratability of each micromirror is provided. Given at least three or five calibration beam paths for at least one portion of the micromirrors, it is possible to attain a minimum number of support points regularly required for a sufficiently accurate calibration of the orientation sensor of a micromirror. Often, however, significantly more calibration beam paths are defined, e.g., nine or more. By virtue of the correspondingly increased number of support points for the calibration, the accuracy of the calibration of a micromirror can regularly be increased further.

If more than one device—calibration radiation source device or calibration radiation sensor device—is provided near the reticle plane, it is preferred for the devices to be arranged near the reticle plane on two opposite sides of the region provided for the exposure of the reticle. If the reticle is displaceable in a scanning direction, the device(s) is/are preferably arranged in such a way that the displaceability of the reticle is not restricted by the devices.

The arrangement according to the disclosed techniques is particularly suitable for illumination systems in which the facet mirror to be calibrated is the field facet mirror for forming one or more virtual light sources on a pupil facet mirror disposed downstream in the beam path and having stationary or merely tiltable facets. Virtual light sources are one or more image representations of the real exposure radiation source, which can be regarded as respectively independent light sources, however, in the further course of the exposure and projection optical unit.

It is preferable for the micromirrors of the facet mirrors to each be pivotable about two non-parallel axes—preferably mutually perpendicular axes—such that the normal vector of the mirror can sweep over a 2-D angular space, generally in conical or pyramidal fashion. Corresponding micromirrors permit great variability in the intensity distribution when illuminating the reticle.

Further details in relation to the arrangement according to the disclosed techniques also emerge from the following explanations in relation to the method according to the disclosed techniques, the method relating to the system-integrated calibration of the facet mirrors of a microlithographic illumination system rendered possible by the arrangement according to the disclosed techniques.

The basis for the method according to the disclosed techniques is a calibration beam path—defined at the outset—which leads from a predefined calibration radiation source device through the exposure optical unit, i.e., in particular also or at least via two facet mirrors, at least one of which is constructed from micromirrors, to a predefined calibration radiation sensor device. Corresponding beam paths can generally be defined without any problems on account of, in particular, the highly accurate positionally fixed arrangement of the various components in a microlithographic illumination system, and also the respective known optical properties thereof.

If a defined calibration beam path is present, then the single micromirror involved in this calibration beam path can be pivoted, in particular, systematically and with observation of the signal of the calibration radiation sensor device until the orientation of the micromirror corresponds to the orientation provided for the defined calibration beam path. Specifically, the systematic pivoting means that the beam path emanating from the micromirror possibly does not impinge or only partly impinges on the downstream optical element, such as, for example, a stationary or merely tiltable facet of a downstream facet mirror, thus resulting in a loss in the case of the radiation ultimately reaching the calibration radiation sensor, and/or the beam path possibly does not impinge on the calibration radiation sensor device, only partly impinges thereon or—in the case of a configuration as an array sensor—at least does not impinge thereon at the position expected for the defined calibration beams. At least when the actual orientation of the micromirror corresponds to the orientation provided for the defined calibration beam, a signal indicating this with sufficient certainty can be acquired at the calibration radiation sensor device. The in particular systematic pivoting of the micromirror can in this case be restricted to the pivot range in which the calibration beam path is actually incident on the calibration radiation sensor device and is detected by this, in principle.

The in particular systematic pivoting of the micromirror is preferably carried out assuming a certain basic calibration. If a suitable basic calibration is assumed, in the event of calibration radiation being detected by the calibration radiation sensor device it can be assumed that the incident radiation reached the calibration radiation sensor device actually in accordance with the defined calibration beam path—rather than, for instance, as a result of reflection via a facet not provided for the defined calibration beam path in the facet mirror not constructed from micromirrors. If a corresponding basic calibration cannot be assumed, e.g.,—if possible—all facet mirrors that are not involved in the defined calibration beam path can however be tilted in such a way that a beam path to the calibration sensor is no longer possible via them. Alternatively, it is possible to determine a basic calibration by moving to the end positions of the microelectromechanical adjustment of the micromirror and the orientation determined for these positions by the orientation sensor.

The in particular systematic pivoting of the micromirror makes it possible to determine an optimum pivot position. Specifically, the optimum pivot position is the one in which the calibration beam path is incident as optimally as possible on the calibration radiation sensor device. In this case, the way in which the calibration beam path can be incident “as optimally as possible” on the calibration radiation sensor device is dependent on the configuration of the latter.

In the case of a binary calibration radiation sensor device, which can only ascertain whether or not radiation is incident on it, e.g., limits of the pivot range at which calibration radiation is still incident on the calibration radiation sensor device can be determined and the optimum pivot position can be calculated therefrom by way of geometric considerations and can subsequently be moved to in order that the orientation determined by the orientation sensor is read off for this pivot position.

If the calibration radiation sensor device is an intensity detector, the optimum pivot position is regularly present when the measured intensity is at a maximum. If, during the recording of the intensity by way of the orientation determined by the orientation sensor, an unambiguous maximum cannot be determined directly, e.g., because a plateau of maximum intensity was determined, it is also possible to use the central maximum of the intensity determined by the radiation detector, the slopes of the rise and fall of the intensity during the in particular systematic pivoting of the micromirror, and/or the centroid of the corresponding intensity profile, in order to determine the optimum pivot position.

If the calibration radiation sensor device involved in the calibration beam path is a one- or two-dimensional array sensor—optionally in addition to the intensity—the optimum pivot position is present when the beam path incident on the sensor or the centre point of said beam path is incident at the position to be expected on the basis of the defined calibration beam path. In principle, it is possible to pivot the micromirror in particular systematically until the calibration beam is actually incident on the expected position on the calibration radiation sensor; however, it is also possible, in the event of incidence at a position deviating therefrom, to determine the instantaneous actual orientation of the micromirror computationally and to use this as a basis for the subsequent calibration instead of the orientation on which the defined calibration beam path is based. It is also possible that the beam path incident on the sensor or the centre point of said beam path is incident at the position to be expected for a plurality of different pivot positions. The optimum pivot position can then generally be determined, however, by way of the profile of the measured pivot positions for which the beam path is correspondingly incident on the sensor.

Once the optimum pivot position of the micromirror has been determined, the orientation determined by the orientation sensor for the pivot position can be ascertained. In this case, it is possible, in principle, to pivot the micromirror into the pivot position determined as optimal and then to read the orientation determined by the orientation sensor. However, it is preferable for the orientation determined by the orientation sensor also to be recorded in addition to the values of the calibration radiation sensor during the in particular systematic pivoting of the micromirror. Once the optimum pivot position has been determined, the matching orientation determined by the orientation sensor can be read directly from the recorded data.

The orientation of the optimum pivot position for the defined calibration beam path, which orientation has been determined in this way by the orientation sensor of the in particular systematically pivoted micromirror, can be compared with the optimum orientation calculable from the defined calibration beam path in order to thereby ascertain whether the current calibration of the orientation sensor is still correct or whether there are deviations between the orientation determined by the orientation sensor and the value calculated on the basis of the defined calibration beam path which necessitates a recalibration.

In this case, the procedure from in particular systematically pivoting the micromirror (step a) to comparing the orientation determined by way of the orientation sensor with the calculated orientation (step d) can be carried out simultaneously for all axes about which the micromirror can be pivoted. However, it is also possible for the method steps in question to be carried out separately, in particular directly successively, for each of these axes.

If described steps a) to d) from in particular systematically pivoting a micromirror to comparing the orientation determined by way of the orientation sensor with the calculated orientation are carried out for a single calibration beam path, the calibration of the micromirror can be verified for a specific pivot position of the micromirror. However, on account of the regularly non-linear relationship between the signal of the orientation sensor and the orientation of the micromirror, in particular, it is preferable if steps a) to d) for a micromirror to be pivoted in particular systematically are carried out with at least three, preferably with at least five, more preferably at least nine, different defined calibration beam paths. However, for a reliable and accurate calibration of a micromirror, steps a) to d) can also be carried out with 20, 50 or 100 different beam paths.

If a comparison according to step d) has been carried out for all the calibration beam paths provided for a micromirror to be adjusted, the data from the at least one comparison can be used to recalibrate the orientation sensor of the micromirror. In other words, the sensor characteristic curve of the orientation sensor is adapted in such a way that the values determined by the orientation sensor of the micromirror correspond as exactly as possible, but in particular with the desired accuracy, to the actual orientation of the respective micromirror. The required accuracy can be defined e.g., as a maximum of 50 μad, a maximum of 20 μad or a maximum of rad.

During this recalibration, it is possible in particular to adapt an n-dimensional characteristic curve of the tilt sensor, where n corresponds to the number of axes about which the associated micromirror can be pivoted. Depending on the shape of this n-dimensional characteristic curve, steps a) to d) should be carried out with a sufficient number of different beam paths to obtain a suitable number of support points for the recalibration or the adaptation of the characteristic curve.

In principle, the method according to the disclosed techniques and respectively the arrangement according to the disclosed techniques allow a calibration of individual micromirrors in parallel with a microlithographic exposure with the aid of the remaining micromirrors of one facet mirror. In view of the regularly large number of micromirrors and the regularly required time for the calibration of an individual micromirror, it is even preferable to carry out the calibration in parallel with actual exposures in order to minimize downtimes of the illumination system, and hence downtimes of an entire microlithographic projection exposure apparatus, on account of calibration.

In order to keep any conceivable mutual interference of exposure and calibration as small as possible, it is preferable for the calibration radiation source device(s) differing from the exposure radiation source of the illumination system to be spectrally and/or temporally decoupled from the exposure by the exposure radiation source. If calibration radiation source device(s) differing from the exposure radiation source is/are used, suitable choice of the calibration radiation source device(s) can ensure that the latter emits or emit no radiation in the wavelength range relevant to the exposure. As a result of this and as a result of the possible provision of a suitable wavelength filter at the calibration radiation sensor device, it is also possible to at least reduce an interference with the calibration on account of the radiation emanating from the exposure radiation source.

Moreover, the exposure radiation sources used in microlithography are regularly operated in pulsed fashion. Therefore, it is possible to operate the calibration radiation source device(s) provided for calibration purposes only whenever the exposure radiation source does not emit any radiation. In other words, a calibration radiation source device provided for the calibration can be operated in offset-pulsed fashion vis-à-vis the exposure radiation source.

The arrangement according to the disclosed techniques preferably comprises a control device or controller designed to carry out the method according to the disclosed techniques. In particular, this can be an already existing control device of an illumination system designed according to the disclosed techniques or a control device of the microlithographic projection exposure apparatus in which the illumination system is embedded.

The computer program product according to the disclosed techniques comprises program parts which, when loaded into an appropriate control device, are designed to carry out the method according to the disclosed techniques. This is particularly relevant to the microlithographic projection exposure apparatuses which, for other reasons, have an arrangement comparable with the arrangement according to the disclosed techniques and therefore require no further structural modifications for the purpose of carrying out the method according to the disclosed techniques.

### BRIEF DESCRIPTION OF THE DRAWINGS

The disclosed techniques will now be described by way of example on the basis of advantageous embodiments with reference to the accompanying drawings, in which:

FIG. 1: shows a schematic illustration of a microlithographic projection exposure apparatus comprising an arrangement according to the disclosed techniques;

FIG. 2: shows an exemplary intensity signal captured by the arrangement from FIG. 1;

FIG. 3: shows a schematic flow chart of the method according to the disclosed techniques;

FIG. 4 shows a first schematic illustration for further elucidation of the functional principle of the disclosed techniques;

FIG. 5 shows a second schematic illustration for further elucidation of the functional principle of the disclosed techniques;

FIG. 6 shows a third schematic illustration for further elucidation of the functional principle of the disclosed techniques; and

FIG. 7 shows a fourth schematic illustration for further elucidation of the functional principle of the disclosed techniques.

### DETAILED DESCRIPTION

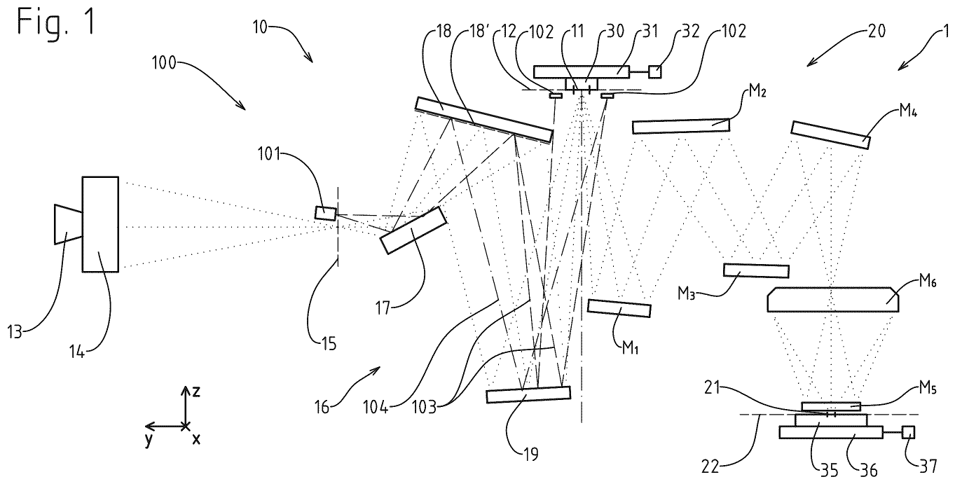

FIG. 1 shows a schematic meridional section of a microlithographic projection exposure apparatus 1. In this case, the projection exposure apparatus 1 comprises an illumination system 10 and a projection system 20, with the illumination system 10 being developed with an arrangement 100 according to the disclosed techniques.

An object field 11 in an object plane or reticle plane 12 is illuminated with the aid of the illumination system 10. To this end, the illumination system 10 comprises an exposure radiation source 13, which, in the illustrated exemplary embodiment, emits illumination radiation at least comprising used light in the EUV range, that is to say with a wavelength of between 5 nm and 30 nm in particular. The exposure radiation source 13 can be a plasma source, for example an LPP (laser produced plasma) source or a GDPP (gas discharge produced plasma) source. It can also be a synchrotron-based radiation source. The exposure radiation source 13 can also be a free electron laser (FEL).

The illumination radiation emanating from the exposure radiation source 13 is initially focused in a collector 14. The collector 14 can be a collector with one or with a plurality of ellipsoidal and/or hyperboloidal reflection surfaces. The illumination radiation can be incident on the at least one reflection surface of the collector 14 with grazing incidence (GI), that is to say at angles of incidence of greater than 45°, or with normal incidence (NI), that is to say at angles of incidence of less than 45°. The collector 14 can be structured and/or coated firstly for optimizing its reflectivity for the used radiation and secondly for suppressing extraneous light.

The illumination radiation propagates through an intermediate focus in an intermediate focal plane 15 downstream of the collector 14. If the illumination system 10 is to be constructed in a modular design, the intermediate focal plane 15 can be used, in principle, for the separation—including the structural separation—of the illumination system 10 into a radiation source module, comprising the exposure radiation source 13 and the collector 14, and the illumination optical unit 16 described below. In the case of a corresponding separation, radiation source module and illumination optical unit 16 then jointly form a modularly constructed illumination system 10.

The illumination optical unit 16 comprises a deflection mirror 17. The deflection mirror 17 can be a plane deflection mirror or, alternatively, a mirror with a beam-influencing effect that goes beyond the pure deflecting effect. Alternatively or additionally, the deflection mirror 17 can be embodied as a spectral filter separating a used light wavelength of the illumination radiation from extraneous light having a wavelength that deviates therefrom.

The deflection mirror 17 is used to deflect the radiation emanating from the exposure radiation source 13 to a first facet mirror 18. If—as in the present case—the first facet mirror 18 is arranged here in a plane of the illumination optical unit 16 which is optically conjugate to the reticle plane 12 as a field plane, this facet mirror is also referred to as a field facet mirror.

The first facet mirror 18 comprises a multiplicity of micromirrors 18′ that are individually pivotable about two mutually perpendicular axes in each case, for the purpose of controllably forming facets which are each configured with an orientation sensor (not depicted) for determining the orientation of the micromirror 18′. The first facet mirror 18 is thus a microelectromechanical system (MEMS system), as also described in DE 10 2008 009 600 A1, for example.

A second facet mirror 19 is arranged downstream of the first facet mirror 18 in the beam path of the illumination optical unit 16, with the result that this yields a doubly faceted system, the fundamental principle of which is also referred to as a fly's eye integrator. If the second facet mirror 19—as in the depicted exemplary embodiment—is arranged in a pupil plane of the illumination optical unit 16, it is also referred to as a pupil facet mirror. However, the second facet mirror 19 can also be arranged at a distance from a pupil plane of the illumination optical unit 16, as a result of which a specular reflector arises from the combination of the first and the second facet mirror 18, 19, for example as described in US 2006/0132747 A1, EP 1 614 008 B1 and U.S. Pat. No. 6,573,978.

The second facet mirror 19 is not constructed from pivotable micromirrors, but rather comprises individual facets formed from one mirror or a manageable number of mirrors which are significantly larger relative to micromirrors, which facets are either stationary or only tiltable between two defined end positions.

The individual facets of the first facet mirror 18 are imaged into the object field 11 with the aid of the second facet mirror 19, with this regularly only being approximate imaging. The second facet mirror 19 can be the last beam-shaping mirror or else actually the last mirror for the illumination radiation in the beam path upstream of the object field 11.

In each case one of the facets of the second facet mirror 19 is assigned to exactly one of the facets of the first facet mirror 18 for the purpose of forming an illumination channel for illuminating the object field 11. This may produce, in particular, illumination according to the Kohler principle.

The facets of the first facet mirror 18 are imaged overlaid on one another by way of a respective assigned facet of the second facet mirror 19, for the purposes of fully illuminating the object field 11. Here, the full illumination of the object field 11 is as homogeneous as possible. It preferably has a uniformity error of less than 2%. The field uniformity can be achieved by overlaying different illumination channels.

By selecting the ultimately used illumination channels, which is possible without problems by way of suitable setting of the micromirrors 18′ of the first facet mirror 18, it is still possible to set the intensity distribution in the entrance pupil of the projection system 20 described below. This intensity distribution is also referred to as illumination setting. Incidentally, it may be advantageous here to arrange the second facet mirror 19 not exactly in a plane that is optically conjugate to a pupil plane of the projection system 20. In particular, the pupil facet mirror 19 can be arranged so as to be tilted relative to a pupil plane of the projection system 20, as is described in DE 10 2017 220 586 A1, for example.

In the arrangement of the components of the illumination optical unit 16 shown in FIG. 1, however, the second facet mirror 19 is arranged in an area conjugate to the entrance pupil of the projection system 20. Deflection mirror 17 and the two facet mirrors 18, 19 are arranged tilted both vis-à-vis the object plane 12 and vis-à-vis one another in each case.

In an alternative embodiment (not depicted) of the illumination optical unit 16, a transfer optical unit comprising one or more mirrors can additionally be provided in the beam path between the second facet mirror 19 and the object field 11. The transfer optical unit can in particular comprise one or two normal-incidence mirrors (NI mirrors) and/or one or two grazing-incidence mirrors (GI mirrors). Using an additional transfer optical unit, it is possible in particular to take account of different poses of the entrance pupil for the tangential and for the sagittal beam path of the projection system 20 described below.

It is alternatively possible for the deflection mirror 17 depicted in FIG. 1 to be dispensed with, for which purpose the facet mirrors 18, 19 should then be suitably arranged vis-à-vis the radiation source 13 and the collector 14.

The object field 11 in the reticle plane 12 is transferred to the image field 21 in the image plane 22 with the aid of the projection system 20.

To this end, the projection system 20 comprises a plurality of mirrors Mi, which are consecutively numbered in accordance with their arrangement in the beam path of the projection exposure apparatus 1.

In the example depicted in FIG. 1, the projection system 20 comprises six mirrors M1 to M6. Alternatives with four, eight, ten, twelve or any other number of mirrors Mi are likewise possible. The penultimate mirror M5 and the last mirror M6 each have a passage opening for the illumination radiation, as a result of which the depicted projection system 20 is a doubly obscured optical unit. The projection system 20 has an image-side numerical aperture that is greater than 0.3 and can also be greater than 0.6, and can be for example 0.7 or 0.75.

The reflection surfaces of the mirrors Mi can be in the form of free-form surfaces without an axis of rotational symmetry. However, the reflection surfaces of the mirrors Mi can alternatively also be designed as aspherical surfaces with exactly one axis of rotational symmetry of the reflection surface shape. Just like the mirrors of the illumination optical unit 16, the mirrors Mi can have highly reflective coatings for the illumination radiation. These coatings can be designed as multilayer coatings, in particular with alternating layers of molybdenum and silicon.

The projection system 20 has a large object-image offset in the y-direction between a y-coordinate of a centre of the object field 11 and a y-coordinate of the centre of the image field 21. This object-image offset in the y-direction can be of approximately the same magnitude as a z-distance between the object plane 12 and the image plane 22.

In particular, the projection system 20 can be designed to be anamorphic, that is to say it has different imaging scales βx, βy in the x- and y-directions in particular. The two imaging scales βx, βy of the projection system 20 are preferably (βx, βy)=(+/−0.25, /+−0.125). An imaging scale R of 0.25 corresponds here to a reduction with a ratio 4:1, while an imaging scale β of 0.125 results in a reduction with a ratio 8:1. A positive sign in the case of the imaging scale β means imaging without image inversion; a negative sign means imaging with image inversion.

Other imaging scales are likewise possible. Imaging scales βx, βy with the same sign and the same absolute magnitude in the x- and y-directions are also possible.

The number of intermediate image planes in the x-direction and in the y-direction in the beam path between the object field 11 and the image field 21 can be the same or different, depending on the embodiment of the projection system 20. Examples of projection systems 20 with different numbers of such intermediate images in the x-direction and y-direction are known from US 2018/0074303 A1.

In particular, the projection system 20 can comprise a homocentric entrance pupil. The latter can be accessible. However, it can also be inaccessible.

A reticle 30 (also referred to as mask) arranged in the object field 11 is exposed by the illumination system 10 and transferred by the projection system 20 onto the image plane 21. The reticle 30 is held by a reticle holder 31. The reticle holder 31 is displaceable in particular in a scanning direction by way of a reticle displacement drive 32. In the exemplary embodiment illustrated, the scanning direction runs in the y-direction.

A structure on the reticle 30 is imaged onto a light-sensitive layer of a wafer 35 arranged in the region of the image field 21 in the image plane 22. The wafer 35 is held by a wafer holder 36. The wafer holder 36 is displaceable by way of a wafer displacement drive 37 in particular longitudinally with respect to the y-direction. The displacement, firstly, of the reticle 30 by way of the reticle displacement drive 32 and, secondly, of the wafer 35 by way of the wafer displacement drive 37 can be implemented so as to be mutually synchronized.

The projection exposure apparatus 1 depicted in FIG. 1 or its illumination system 10, the above description of which substantially reflects the known prior art, is developed using an arrangement 100 according to the disclosed techniques. In this case, the arrangement 100 comprises a calibration radiation source device 101 (i.e., a device that includes a calibration radiation source) and a plurality of calibration radiation sensor devices 102 (i.e., device that include one or more calibration radiation sensors) as structural components.

In the exemplary embodiment illustrated, the calibration radiation source device 101 is designed as a radiation source which is separate from the exposure radiation source 13 and which is arranged in the region of the intermediate focus or the intermediate focal plane 15 of the exposure radiation source 13. However, it is also possible for the exposure radiation source 13 to be used as a calibration radiation source device 101. Moreover, a plurality of calibration radiation source devices 101 can be provided, one of which can be the exposure radiation source 13.

The calibration radiation source device 101 illustrated in FIG. 1 emits light in the visible range, wherein the actual light source is arranged outside the illumination system 10 and the light generated thereby is introduced into the illumination system 10 via a suitable optical fibre at the position of reference numeral 101 illustrated in FIG. 1.

Furthermore, two calibration radiation sensor devices 102 arranged near the reticle plane 12 away from the region provided for the reticle 30 are provided in the exemplary embodiment illustrated. The calibration radiation sensors 102 are arranged on both sides of the scanning direction—running in the y-direction in the example illustrated—in this case, with the result that the actual exposure of the reticle 30 is not disturbed, nor is any displacement of the reticle holder 31 in the scanning direction obstructed.

The calibration radiation sensor devices 102 are each intensity detectors designed for the wavelength of the radiation of the calibration radiation source device 101, each of which intensity detectors is formed with a stop and a narrowband wavelength filter adapted to the radiation of the calibration radiation source device 101.

Calibration beam paths 103, 104, a few of which are indicated by way of example in FIG. 1, can be defined for each individually pivotable micromirror 18′ of the facet mirror 18. The calibration beam paths 103, 104 each lead from the calibration radiation source device 101 via a specific micromirror 18′ of one facet mirror 18 and also a predefined facet on the other facet mirror 19 to a predefined calibration radiation sensor device 102, wherein the facet of the facet mirror 19 is regularly a different facet from the one which is irradiated for the actual exposure of a reticle 30 via the micromirror 18′. Independently, the calibration beam paths 103, 104—as illustrated—can additionally also lead via a deflection mirror 17 and/or an arbitrary further transfer optical unit (not illustrated).

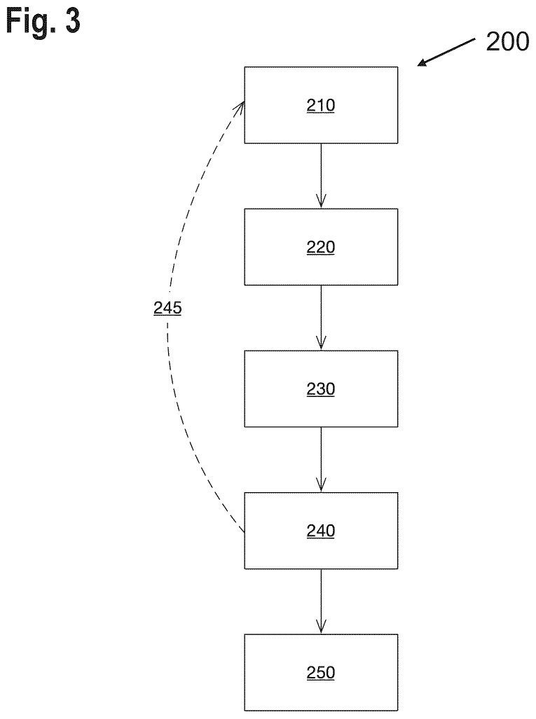

For the use of the arrangement 100 for system-integrated calibration of the facet mirror 18 of the illumination system 10—and thus for carrying out the method 200 according to the disclosed techniques (cf. FIG. 3)—the micromirror 18′ involved in a specific defined calibration beam path 103, 104 is pivoted in particular systematically, while the signal of the calibration radiation sensor device 102 assigned to the respective calibration beam path 103, 104 is simultaneously monitored (cf. FIG. 3, step 210).

In this case, the micromirror 18′ is in particular systematically pivoted at least over the pivot range in which radiation along the defined calibration beam path 103, 104 is incident on the calibration sensor device 102. For this purpose, assuming a certain basic calibration, the micromirror 18′ can be pivoted into the orientation provided for the defined calibration beam path 103, 104, where it can then generally be assumed that radiation incident on the calibration sensor device 102 was actually deflected by the micromirror 18′ in question. In this case, of course, it is necessary to ensure that no other beam path from the calibration radiation source device 101 reaches the calibration radiation sensor device 102, which however is able to be achieved, e.g., by suitable pivoting of the remaining micromirrors 18′ of the facet mirror constructed therefrom, which is generally possible without any problems even if only a basic calibration is present for the remaining micromirrors 18′. In particular, the remaining micromirrors 18′ can also be suitably pivoted for the actual exposure of the reticle 30. Alternatively, the remaining micromirrors 18′ can also be pivoted into respective end positions of their pivot range in which a beam path from the calibration radiation source device 101 to the calibration radiation sensor device 102 is not realizable via the micromirrors 18′ in question. Analogously—if possible—the facets of the other facet mirror 19 that are not involved in the defined calibration beam path 103, 104 can also be tilted into a defined position in which no radiation coming from the first facet mirror 18 is deflected in the direction of the calibration radiation sensor device 102.

In this case, if no radiation can be detected by the calibration radiation sensor device 102, in the exemplary embodiment illustrated this can mean either that the calibration radiation reflected by the micromirror 18′ is not incident on any radiation-reflecting facet of the other facet mirror 19, or that the radiation that is deflected by the facet mirror 19 and comes from the micromirror 18′ is simply not incident on the calibration radiation sensor device 102.

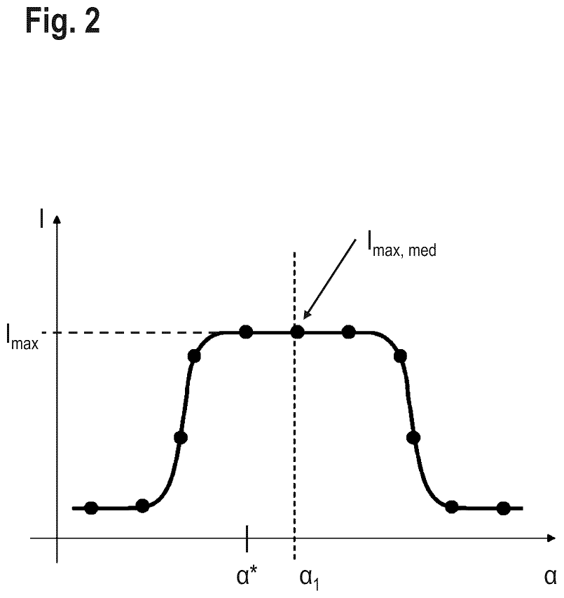

If the micromirror 18′ to be calibrated is pivoted accordingly, the intensity I of the incident radiation determined by the calibration radiation sensor device 102 can be recorded as a function of the orientation a captured by the orientation sensor of the micromirror 18′, as is illustrated by way of example in FIG. 2. In this case, the illustration in FIG. 2 is restricted to pivoting on a pivot axis of the micromirrors 18′ perpendicular to the plane of the drawing. If, as in the present case, the micromirrors 18′ are pivotable about two axes, the in particular systematic pivoting can also be carried out over each of the axes, it being possible to consider the two axes simultaneously or successively with a temporal offset.

From the data thus recorded, it is possible to determine the optimum pivot position of the in particular systematically pivoted micromirror 18′ (cf. FIG. 3, step 220), for which optimum pivot position the calibration beam path 103, 104 is incident on the calibration radiation sensor 102. In the present example here, the optimum pivot position corresponds to the central maximum of the intensity Imax, med.

For the optimum pivot position with intensity Imax, med thus determined, it is possible to determine from the recorded data the orientation al of the in particular systematically pivoted micromirror 18′ indicated by the orientation sensor of the micromirror (cf. FIG. 3, step 230).

On the basis of the knowledge of the arrangement of calibration radiation source device 101, the facet mirrors 18, 19 and in particular the micromirror 18′ and also the calibration radiation sensor device 102, it is also possible to calculate that orientation α* of the in particular systematically pivoted micromirror 18′ which should correspond to the optimum pivot position and should actually have been indicated by the orientation sensor. By comparing the orientation al detected by the orientation sensor for the optimum pivot position with the orientation α* calculated for this pivot position (cf. FIG. 3, step 240), it is already possible, in principle, to adapt the calibration of the orientation sensor for this one pivot position on the basis of the comparison (cf. FIG. 2, step 250).

However, for a specific micromirror 18′ to be pivoted in particular systematically, provision is made for the above-described steps 200-240 to be carried out for a plurality of defined calibration beam paths 103, as is indicated in FIG. 1 (cf. FIG. 3, arrow 245). In particular, a total of, for example, five different calibration beam paths 103 can be provided for a micromirror 18′ which is pivotable about two axes. In this case, the five calibration beam paths 103 are preferably defined such that the orientations to be adopted therefor by the micromirror 18′ to be calibrated do not lie in a common plane.

This yields a total of five of the described comparisons of detected and calculated orientations α1, α* for the respectively optimum pivot positions of the micromirror 18′ to be pivoted, in each case for one beam path 103 (cf. FIG. 3, step 240), and these can be used to recalibrate the orientation sensor of the micromirror 18′ (cf FIG. 3, step 250).

This is helpful, in particular, for orientation sensors which have a possibly non-linear, two-dimensional characteristic curve on account of pivotability about two separate axes since the five support points arising from the aforementioned five comparisons are generally enough to adapt the two-dimensional characteristic curve of the orientation sensor over the entire pivot range, and thus to achieve a complete recalibration of the orientation sensor. Depending on the characteristic curve of the orientation sensor or the required accuracy of the calibration, however, it is naturally also possible that significantly more calibration beam paths 103, 104 and resultant comparisons are required to carry out a suitable calibration.

In order to be able to define a sufficient number of calibration beam paths 103, 104 for the calibration of each micromirror 18′ of the facet mirror 18, it may be necessary to provide more than two calibration radiation sensor devices 102 or additional calibration radiation source devices 101. In particular, in this case a plurality of calibration radiation sensor devices 102 can be arranged in series on both sides of the reticle holder 31. However, it is also possible, for example, for the calibration radiation sensor devices 102 to be formed as one- or two-dimensional array sensors which are designed in each case for the wavelength from the calibration radiation source device 101. Such sensor arrays enable the incidence position in at least one direction also to be determined, as well as the intensity of the radiation incident on the array sensor. The position of the incidence of the calibration beam path 103, 104 on the calibration radiation sensor device 102 is then suitably taken into account during the calibration of the orientation sensor of a micromirror 18′.

In accordance with an alternative embodiment, the at least one calibration radiation sensor device 102 is arranged in the region of the intermediate focus 15′ of the exposure radiation source 13, and the at least one calibration radiation source device 101 is arranged near the reticle plane 12 away from the region provided for the reticle 30.

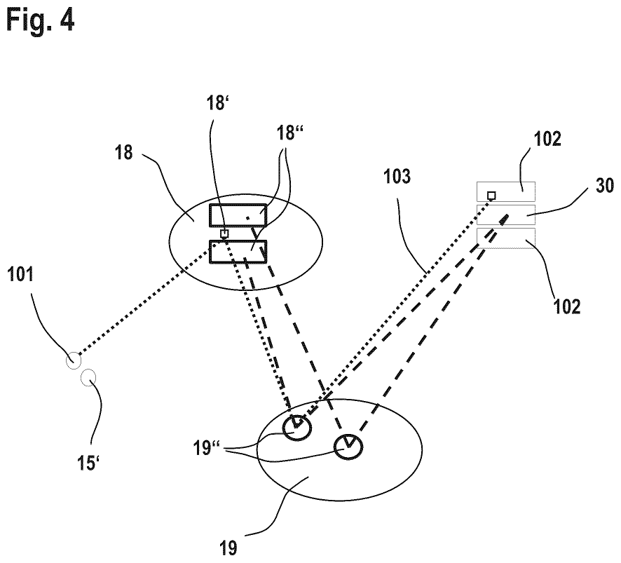

The functional principle of the disclosed techniques is illustrated schematically again in FIGS. 4 to 7. In this case, the dashed lines indicate parts of beam paths for the actual exposure of a reticle 30, while the dotted lines are calibration beam paths 103.

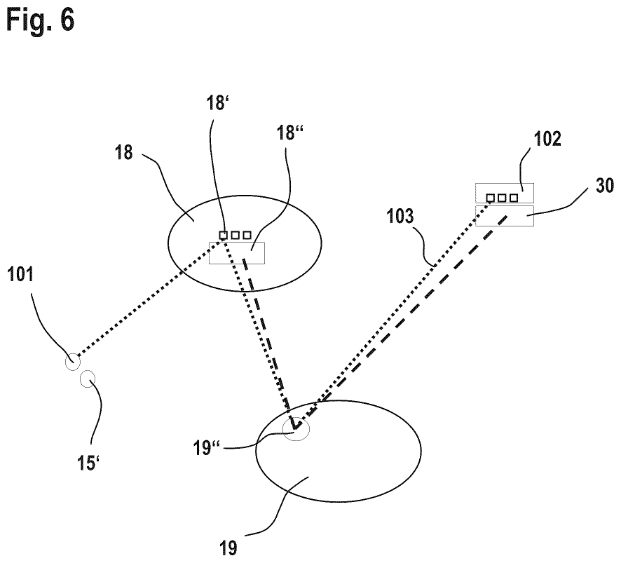

For the calibration of the orientation sensors of the micromirrors 18′ on a field facet mirror 18 in which a group of micromirrors 18′ can in each case form a (virtual) field facet 18″, the imaging properties of the pupil facets 19″ of the other facet mirror 19 are exploited in order that the calibration beam path 103 passing from a calibration radiation source device 101 in the region of the intermediate focus 15′ via a micromirror 18′, in the region of the reticle 30, in a manner displaced in the scanning direction, is caused to be incident on a calibration radiation sensor device 102 arranged there (cf. FIG. 6). However, the calibration beam path 103 reaches the calibration radiation sensor device 102 only if the micromirror 18′ to be calibrated is tilted such that the radiation from the calibration radiation source device 101 also actually impinges on the (virtual) pupil facet 19″ applicable to the desired calibration beam path 103. In this case, it is possible to ascertain, for example, a top-hat-like excursion at the calibration radiation sensor device 102 as a function of the tilt angle of the micromirror 18′ to be calibrated, as is shown by way of example in FIG. 2.

In order to satisfy the requirement for a plurality of such calibration beam paths 103, it is possible to make use of one (virtual) (partial) field facet 18″ being assigned to a plurality of (virtual) pupil facets 19″. This assignment can be fixed or dynamically variable.

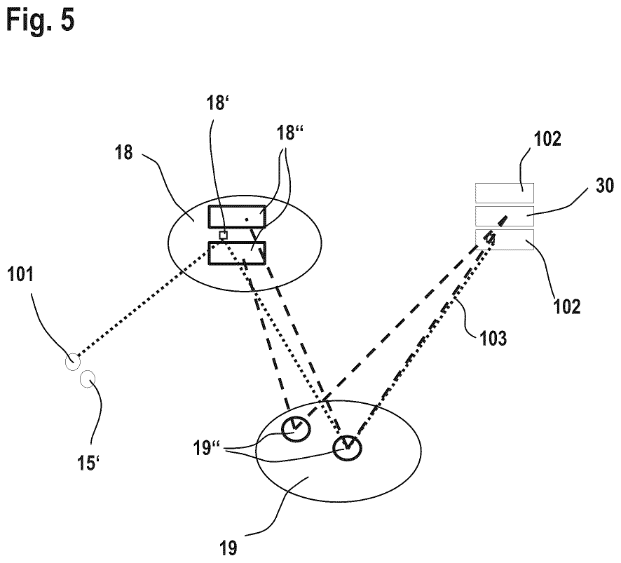

In this case, it is advantageous if the calibration radiation sensor device 102 has an active surface both (in the scanning direction) above and (in the scanning direction) below the reticle 30. It is then possible to choose freely whether a micromirror 18′ to be calibrated is calibrated via a (virtual) pupil facet 19″ of the virtual (partial) field facet 18″ situated above (cf. FIG. 4) or via a (virtual) pupil facet 19″ of the virtual (partial) field facet 18″ situated below (cf. FIG. 5).

If permitted by the resolution of the calibration radiation sensor device 102, it is also possible for a plurality of micromirrors 18′ to be calibrated simultaneously. For this purpose, it is possible to direct e.g., a plurality of micromirrors 18′ from the vicinity of a single virtual (partial) field facet 18″ onto the (virtual) pupil facet 19″ associated therewith (cf FIG. 6).

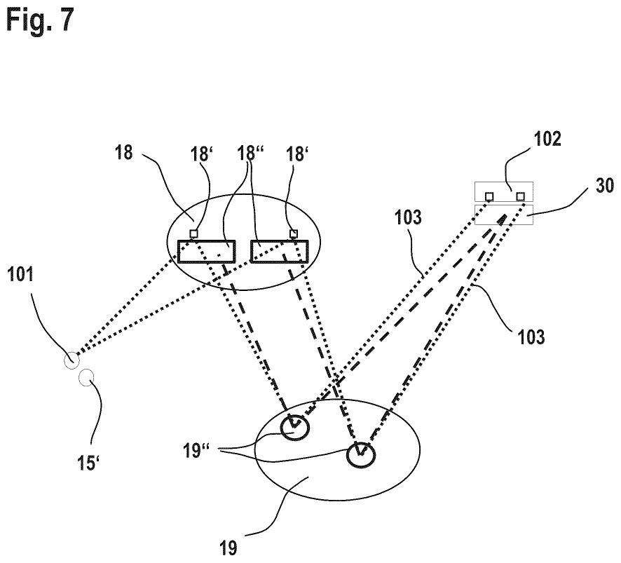

Alternatively, it is also possible to direct a plurality of micromirrors 18′ from the vicinities of different virtual (partial) field facets 18′ onto the respectively associated (virtual) pupil facets 19′ (cf FIG. 7). In this case, care should be taken to ensure that the images of the micromirrors 18′ to be calibrated are not too close together, since otherwise the signals of the two micromirrors 18′ could be superimposed on the calibration radiation sensor device 102.

What is claimed is:

1. An apparatus comprising:
a facet mirror to be calibrated comprising:
a microelectromechanical system with a plurality of individually pivotable micromirrors, wherein each of the plurality of individually pivotable micromirrors is arranged positionally fixedly in a beam path of an illumination optical unit of an illumination system in such a way that beams emanating from an exposure radiation source are deflected onto a reticle plane of the illumination system by an exposure optical unit comprising the facet mirror to be calibrated and a further facet mirror without a microelectromechanical system; and
a respective orientation sensor for each of the plurality of individually pivotable micromirrors, wherein each respective orientation sensor is configured to determine an orientation of a respective micromirror;
a calibration radiation source; and
a calibration radiation sensor;
wherein a first of the calibration radiation source or the calibration radiation sensor is arranged near the reticle plane of the illumination system away from a region of the reticle plane that provides a reticle, and an other of the calibration radiation source or the calibration radiation sensor is arranged such that at least one calibration beam path is provided between the calibration radiation source and the calibration radiation sensor via a predefined micromirror of the facet mirror to be calibrated, given a suitable pivot position of the predefined micromirror, and a predefined facet of the further facet mirror.

2. The apparatus of claim 1, wherein a number, an arrangement and/or a configuration of the calibration radiation source and/or of the calibration radiation sensor is chosen in such a way that at least one calibration beam path is provide for at least a portion of the facet mirror to be calibrated.

3. The apparatus of claim 1, wherein the first of the calibration radiation source or the calibration radiation sensor is configured in planar fashion and/or provided on opposite sides of the region of the reticle plane that provides the reticle.

4. The apparatus of claim 1, wherein the other of the calibration radiation source or the calibration radiation sensor is arranged near or in an intermediate focal plane of the illumination system.

5. The apparatus of claim 1, wherein the calibration radiation sensor is an intensity detector, a one-dimensional array sensor or a two-dimensional array sensor.

6. The apparatus of claim 1, wherein the calibration radiation sensor is provided with a bandpass filter adapted to a wavelength of the calibration radiation source.

7. The apparatus of claim 1, wherein the calibration radiation source is the exposure radiation source of the illumination system or a separate radiation source.

8. The apparatus of claim 7, wherein the exposure radiation source of the illumination system comprises an EUV radiation source.

9. The apparatus of claim 1, wherein the calibration radiation source is designed for emitting light in a visible range.

10. The apparatus of claim 1, wherein the facet mirror to be calibrated comprises a field facet mirror for forming one or more virtual light sources on a pupil facet mirror disposed downstream in the beam path and having stationary or merely tiltable facets.

11. The apparatus of claim 1, wherein each of the plurality of individually pivotable micromirrors is pivotable about two non-parallel axes.

12. A method for calibrating a facet mirror—constructed from micromirrors—of a microlithographic illumination system comprising:
pivoting a micromirror of a facet mirror, the micromirror providing a calibration beam path leading from a calibration radiation source via an illumination optical unit comprising at least two facet mirrors to a calibration radiation sensor, at least over a pivot range of the micromirror in which the calibration beam path is incident on the calibration radiation sensor and is detected by the calibration radiation sensor;
determining an optimum pivot position of the micromirror via the calibration radiation sensor, wherein the calibration beam path is incident optimally on the calibration radiation sensor;
ascertaining an orientation of the micromirror determined by an orientation sensor of the micromirror for the optimum pivot position;
comparing the orientation of the micromirror determined by the orientation sensor of the micromirror with an orientation calculated from the calibration beam path; and
recalibrating the orientation sensor of the micromirror based on the comparing.

13. The method of claim 12, further comprising: ascertaining an optimum incidence of the calibration beam path by using a maximum of an intensity determined by a calibration radiation sensor designed as an intensity detector during the pivoting the micromirror, a central maximum of the intensity determined by the calibration radiation sensor designed as an intensity detector during the pivoting the micromirror, slopes of a rise and fall of the intensity determined by the calibration radiation sensor designed as an intensity detector during the pivoting the micromirror, a centroid of the intensity determined by the calibration radiation sensor designed as an intensity detector during the pivoting the micromirror, and/or an incidence position of the calibration radiation sensor designed as a one- or two-dimensional array sensor.

14. The method of claim 12 furthering comprising performing the method for each pivot axis of the micromirror to be pivoted.

15. The method of claim 12, further comprising performing the method for the micromirror of the facet mirror with at least three different calibration beam paths.

16. The method of claim 12, wherein recalibrating the orientation sensor comprises adapting an n-dimensional characteristic curve of the orientation sensor, where n corresponds to a number of axes about which the micromirror can be pivoted.

17. The method of claim 12, the method is performed in parallel with a microlithographic exposure implemented via other micromirrors of the facet mirror.

18. The method of claim 12, wherein the calibration radiation source differs from an exposure radiation source of an illumination system and wherein the calibration radiation source is spectrally and/or temporally decoupled from exposure provided by the exposure radiation source.

19. The method of claim 12, where in the method if performed in response to instructions provided by a controller.

20. One or more tangible, non-transitory mediums encoded with instructions, wherein the instructions, when implemented by one or more processors, cause the one or more processors to:
control pivoting of a micromirror of a facet mirror, the micromirror providing a calibration beam path leading from a calibration radiation source via an illumination optical unit comprising at least two facet mirrors to a calibration radiation sensor, at least over a pivot range of the micromirror in which the calibration beam path is incident on the calibration radiation sensor and is detected by the calibration radiation sensor;
determine an optimum pivot position of the micromirror via the calibration radiation sensor, wherein the calibration beam path is incident optimally on the calibration radiation sensor;
ascertain an orientation of the micromirror determined by an orientation sensor of the micromirror for the optimum pivot position;
compare the orientation of the micromirror determined by the orientation sensor of the micromirror with an orientation calculated from the calibration beam path; and
recalibrate the orientation sensor of the micromirror based on the comparing.
